(19) United States
(12) Patent Application Publication
(10) Pub. No.: US 2012/0073755 A1
(43) Pub. Date: Mar. 29, 2012

(54) ELECTRODE AND PLASMA PROCESSING APPARATUS

(75) Inventor: Daisuke Hayashi, Miyagi (JP)

(73) Assignee: TOKYO ELECTRON LIMITED, Tokyo (JP)

(21) Appl. No.: 13/246,018

(22) Filed: Sep. 27, 2011

Related U.S. Application Data
(60) Provisional application No. 61/391,906, filed on Oct. 11, 2010.

(30) Foreign Application Priority Data
Sep. 27, 2010 (JP) 2010-215314

(51) Int. Cl. H01L 21/67

(52) U.S. Cl. 156/345.34

(57) ABSTRACT

Electric field intensity distribution of a high frequency power for plasma generation can be controlled without generating abnormal electric discharge. There is provided an electrode for a plasma processing apparatus capable of supplying a gas. The electrode may include a base member 105a made of a dielectric material and having therein a certain space U; a cover 107 for airtightly sealing the space U and isolating the space U from a plasma generation space when the electrode is installed at the plasma processing apparatus; and multiple gas hole tubes 105e passing through the cover member 107, the space U and the base member 105a. Each gas hole tube has a gas hole isolated from the space U.

### CROSS-REFERENCE TO RELATED APPLICATION

This application claims the benefit of Japanese Patent Application No. 2010-215314 filed on Sep. 27, 2010, and U.S. Provisional Application Ser. No. 61/391,906 filed on Oct. 11, 2010, the entire disclosures of which are incorporated herein by reference.

### FIELD OF THE INVENTION

The present disclosure relates to an electrode used for a plasma processing apparatus and a plasma processing apparatus using the electrode. More particularly, the present disclosure relates to an electrode capable of controlling electric field intensity distribution of a high frequency power for plasma generation and a plasma processing apparatus using the electrode.

### BACKGROUND OF THE INVENTION

With the recent demand for miniaturization, it has become necessary to generate high-density plasma by supplying a relatively high frequency power. As illustrated in FIG. 7, when a frequency of a power supplied from a high frequency power supply 150 is increased, a high frequency current flows along a lower surface of a lower electrode 110, and then, flows along a top surface of the lower electrode 110 from an edge portion the lower electrode 110 toward a central portion thereof by a skin effect. Therefore, the electric field intensity at the central portion of the lower electrode becomes higher than electric field intensity at the edge portion of the lower electrode 110. Accordingly, ionization or dissociation of a gas is accelerated at the central portion of the lower electrode 110 than at the edge portion of the lower electrode 110. As a consequence, electron density of plasma at the central portion of the lower electrode 110 becomes higher than electron density of plasma at the edge portion thereof. Since a resistivity of the plasma is decreased at the central portion of the lower electrode 110 where the electron density of plasma is high, a high frequency current is concentrated at the central portion of an upper electrode 105 facing the lower electrode 110. Therefore, plasma density at a central portion of a plasma generation space becomes higher than plasma density at a peripheral portion thereof. This results in non-uniformity of the plasma density.

In order to improve uniformity of the plasma density, Patent Document 1 describes an upper electrode including an electrode plate facing a susceptor; and an electrode supporting plate, provided above the electrode plate, for supporting the electrode plate. In this upper electrode, a hollow portion is formed at a center of a contact portion between the electrode plate and the electrode supporting plate. Due to the presence of the hollow portion, the electric field intensity below the hollow portion is decreased. Accordingly, the plasma density at the lower central portion of the electrode is decreased, and this allows the plasma density to be uniformized.
Patent Document 1: Japanese Patent Laid-open Publication No. 2007-250838

However, in Patent Document 1, the hollow portion of the upper electrode and the plasma processing space in the chamber communicate with each other. Further, the hollow portion and a gas supply passageway communicate with each other. For that reason, a gas or a plasma easily enter the hollow portion, which may cause abnormal electric discharge in the hollow portion.

### BRIEF SUMMARY OF THE INVENTION

In view of the above, the present disclosure provides an electrode capable of controlling electric field intensity distribution of a high frequency power for plasma generation without generating abnormal electric discharge in a space inside the electrode, and a plasma processing apparatus using the electrode.

In accordance with an aspect of the present disclosure, there is provided an electrode for a plasma processing apparatus capable of supplying a gas. The electrode may include a base member made of a dielectric material and having therein a space; a cover member for airtightly sealing the space and isolating the space from a plasma generation space when the electrode is installed at the plasma processing apparatus; and multiple gas hole tubes passing through the cover member, the space and the base member. Each gas hole tube has a gas hole isolated from the space.

With this configuration, the space formed in the base member can be considered as a dielectric layer having a dielectric constant (∈₀) of about 1. By using the space, there is made a difference between the dielectric constant (∈) of the base member and the dielectric constant (∈₀) of the space. Here, the dielectric constant (∈₀) of the space is about 1, which is the lowest value among the dielectric constants of dielectric materials. In view of the electrostatic capacitance, an area where the space U1 is formed as depicted in a left part of FIG. 4 has an effect equal to a structure where a dielectric member of the base member becomes thick as depicted as a portion A protruding from a flat portion B in a right part of FIG. 4. Therefore, in the present disclosure, the difference between the capacitance of the base member and the capacitance of the space portion can be more increased by forming the entire space U as the hollow region in the electrode instead of providing partition or fine holes therein. In other words, it is equivalent to a case where the portion A shown in FIG. 4 is more protruded from the flat portion B.

The space may have an atmospheric pressure.

Further, the space may be formed by a recess formed in the base member and the cover member may be configured to seal the recess. The recess may be airtightly sealed by performing diffusion joint between the cover member and the base member made of silicon oxide.

The recess may have a taper shape or a step shape.

The recess may be formed such that a depth thereof may become deeper toward a central portion and become shallower toward a peripheral portion thereof.

The multiple gas hole tubes may be spaced apart from each other at a regular interval to supply a gas in a shower shape.

The electrode may further include a plate-shaped electrode cover made of a material same as that of the base member, and provided adjacent to a surface of the electrode facing the plasma generation space.

Each gas hole tube may have a diameter of about 5 mm to about 10 mm.

In accordance with another aspect of the present disclosure, there is provided a plasma processing apparatus including a processing chamber; a first electrode and a second electrode facing each other in the processing chamber, and having a plasma generation space therebetween; and a gas supply source for supplying a gas into the processing chamber. The first electrode may include a base member made of a dielectric material and having therein a space; a cover member for airtightly sealing the space and isolating the space from a plasma generation space when the electrode is installed at the plasma processing apparatus; and multiple gas hole tubes passing through the cover member, the space and the base member. Each gas hole tube may have a gas hole isolated from the space.

The first electrode may be an upper electrode.

As described above, in accordance with the present disclosure, the electric field intensity distribution of the high frequency power for plasma generation can be controlled without generating abnormal electric discharge in the space inside the electrode.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a longitudinal cross sectional view of a RIE plasma etching apparatus in accordance with an embodiment of the present disclosure.

FIG. 2A is a longitudinal cross sectional view of a general upper electrode and FIG. 2B is a longitudinal cross sectional view of an electrode in accordance with the embodiment.

FIG. 3 is a view showing arrangement of gas hole columns provided at a base member of the electrode in accordance with the embodiment.

FIG. 4 is a view illustrating a function of a space provided in the base member of the electrode in accordance with the embodiment.

FIGS. 5A to 5C are views illustrating functions of spaces formed in the base member of the present embodiment as shown in FIGS. 5A and 5B, and a function of a space in accordance with a comparative example as shown in FIG. 5C.

FIGS. 6A to 6C are views illustrating examples of spaces formed in the base member of the electrode in accordance with the embodiment.

FIG. 7 is a view illustrating a high frequency current applied to a general plasma apparatus.

### DETAILED DESCRIPTION OF THE INVENTION

Hereinafter, the embodiments of the present disclosure will be described in detail with reference to the accompanying drawings. In the specification and the accompanying drawings, like reference numerals will be given to like parts having substantially the same functions and configurations, and redundant description thereof will be omitted.

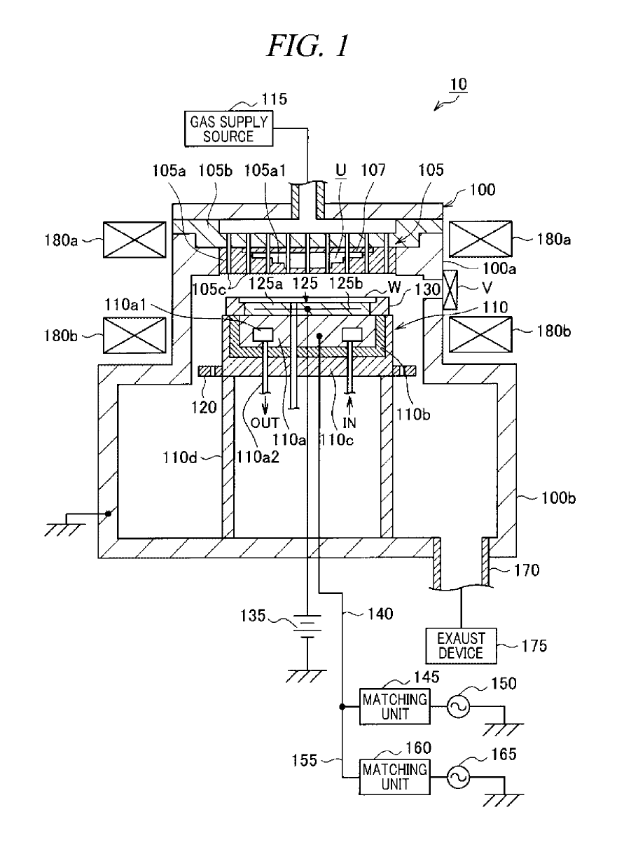

First, a RIE plasma etching apparatus (parallel plate type plasma processing apparatus) using an electrode in accordance with an embodiment of the present disclosure will be described with reference to FIG. 1. A RIE plasma etching apparatus 10 is an apparatus for etching a wafer W, and an example of a plasma processing apparatus that performs a desired processing on an object to be processed.

The RIE plasma etching apparatus 10 may include a processing chamber 100 that can be depressurized. The processing chamber 100 may include an upper chamber 100a having a small diameter and a lower chamber 100b having a large diameter. The processing chamber 100 may be made of a metal, e.g., aluminum and may be grounded.

In the processing chamber 100, an upper electrode 105 and a lower electrode 110 may be provided at an upper portion and a lower portion of the chamber 100, respectively, to face each other. A wafer W may be loaded into the processing chamber 100 through a gate valve V and is mounted on the lower electrode 110.

The upper electrode 105 may include a base member 105a and a base plate 105b on the base member 105a. The base member 105a may be made of quartz. However, the base member 105a may not be limited to quartz, but it may be made of a dielectric material such as alumina (Al₂O₃), silicon nitride (Si₃N₄), aluminum nitride (AlN), yttria (Y₂O₃), TEFLON (Registered Trademark: polytetrafluoroethylene), or the like.

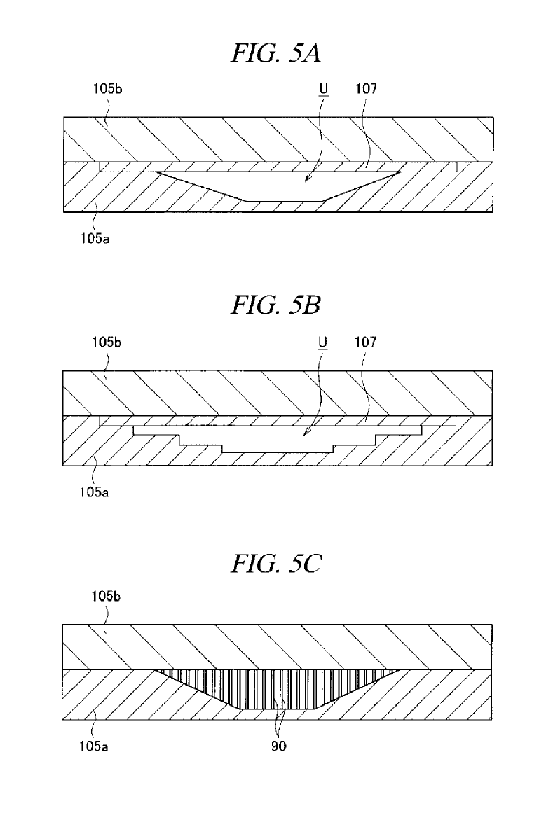

A recess 105a1 may be formed at an upper central portion of the base member 105a, and a bottom surface of the recess 105a1 may have a stepped shape (refer to FIG. 5B). However, the recess 105a1 may be formed in a tapered shape (FIG. 5A). In both cases, the recess 105a1 may be formed such that a depth thereof may become larger toward a central portion and smaller toward a peripheral portion thereof.

A cover 107 for sealing the recess 105a1 may be provided at an upper portion of the recess 105a1. Accordingly, a certain space U is formed in the base member 105a. The cover 107 may be made of quartz, the same as the base member 105a. The cover 107 may be an example of a member for airtightly sealing the certain space U to thereby isolate the space U from a plasma generation space when the upper electrode 105 is provided in the RIE plasma etching apparatus 10. Further, a junction method of the base member 105a and the cover 107 will be described later.

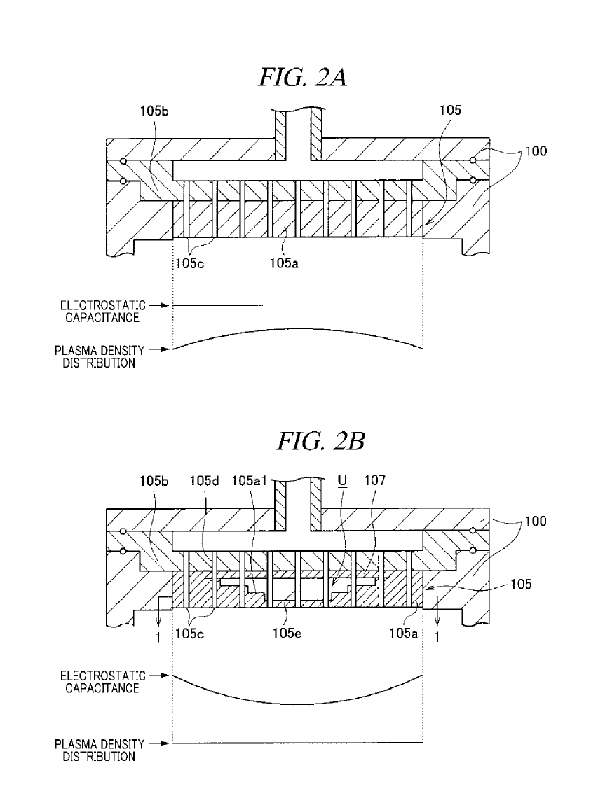

A gas supplied from a gas supply source 115 may be diffused in a diffusion space formed by the conductive base plate 105b and the processing chamber 100. As shown in FIG. 2B illustrating an enlarged longitudinal cross sectional view of the upper electrode 105, the gas may be introduced into the processing chamber through multiple gas holes 105c via multiple gas passages 105d and multiple gas hole tubes 105e provided in the base member 105a. With this configuration, the upper electrode 105 also may serve as a shower head. Alternatively, the upper electrode 105 may not have the base plate 105b, and instead, the base 105a may be directly connected to a ceiling plate of the processing chamber 100.

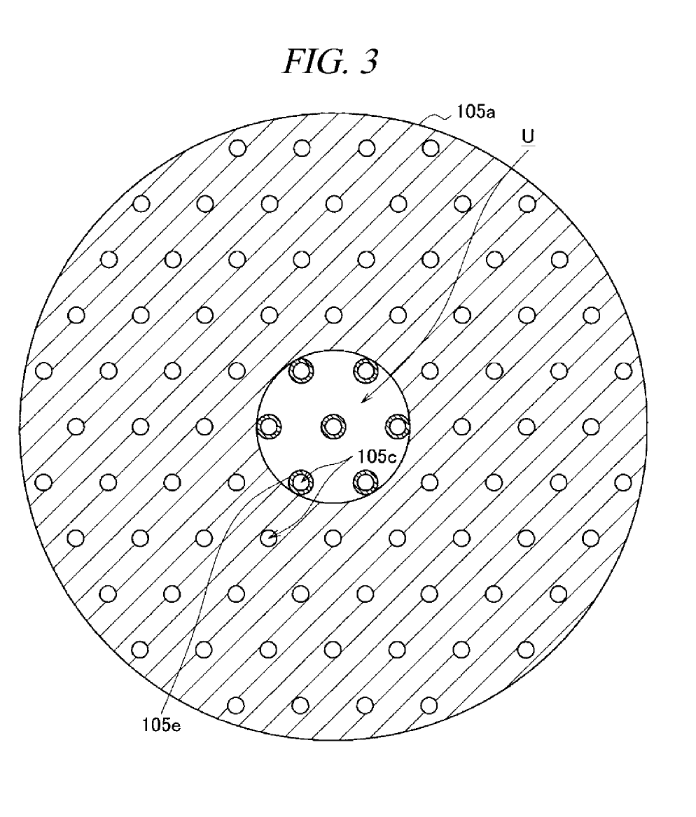

FIG. 3 illustrates a transversal cross sectional view (a cross section taken along a line 1-1 of FIG. 2B) of the base member 105a of the upper electrode 105 in accordance with the embodiment. The multiple gas hole tubes 105e may penetrate the base member 105a. The gas hole tubes 105e may be spaced apart from each other at a regular interval to supply the gas in a shower shape. Further, the gas hole tubes 105e may penetrate the base member 105a and the cover 107 through the recess 105a1 serving as a certain space. Spaces of the gas holes 105c within the gas hole tubes 105e are isolated from the space of the recess 105a1. The arrangement of the gas holes 105c may not be limited to the arrangement shown in FIG. 3 as long as the gas can be uniformly supplied into the processing chamber.

Referring back to FIG. 1, the lower electrode 110 may include a base member 110a made of a metal, e.g., aluminum, and the base member 110a may be supported on a supporting table 110c via an insulating layer 110b. The lower electrode 110 may be in a electrically floating state. A lower portion of the supporting table 110c may be covered with a cover 110d. A baffle plate 120 may be provided at a lower outer periphery of the supporting table 110c so as to control a gas flow.

A coolant cavity 110a1 may be formed in the lower electrode 110. A coolant is introduced through a coolant inlet line 110a2 in a direction as indicated by an arrow IN and circulated in the coolant cavity 110a1, and then, discharged through the coolant inlet line 110a2 in a direction as indicated by an arrow OUT. Accordingly, the lower electrode 110 can be controlled to a desired temperature.

An electrostatic chuck 125 provided on the lower electrode 110 may include an electrode 125b made of a metal sheet member and embedded in an insulating member 125a. A DC power supply 135 is connected to the electrode 125b, and a DC voltage outputted from the DC power supply 135 is applied to the electrode 125b. As a result, the wafer W may be electrostatically attracted and held to the lower electrode 110. A focus ring 130 made of, e.g., silicon, may be provided at an outer periphery of the electrostatic chuck 125 to maintain uniformity of plasma.

The lower electrode 110 may be connected to a first matching unit 145 and a first high frequency power supply 150 via a first power supply rod 140. The gas within the processing chamber may be excited into plasma by electric field energy of a high frequency power for plasma excitation output from the first high frequency power supply 150. By the electric discharge plasma generated in this way, an etching process may be performed on the wafer W. In the present embodiment, the upper electrode 105 is referred to as a first electrode and the lower electrode 110 is referred to as a second electrode. However, the first electrode may be the upper electrode 105 or the lower electrode 110. Likewise, the second electrode may be the upper electrode 105 or the lower electrode 110. The high frequency power for plasma excitation may have a frequency equal to or higher than about 60 MHz. Desirably, the high frequency power for plasma excitation may be equal to or higher than about 100 MHz.

Moreover, the lower electrode 110 may be connected to a second matching unit 160 and a second high frequency power supply 165 via a second power supply rod 155 branched from the first power supply rod 140. A high frequency power of, e.g., about 3.2 MHz output from the second high frequency power supply 165 may be used as a bias voltage to attract ions into the lower electrode 110.

A gas exhaust port 170 may be formed at a bottom surface of the processing chamber 100. By operating a gas exhaust device 175 connected to the gas exhaust port 170, the inside of the processing chamber 100 can be maintained in a desired vacuum state.

Multi-pole ring magnets 180a and 180b may be arranged around the upper chamber 100a. In each of the multi-pole ring magnets 180a and 180b, multiple columnar anisotropic segment magnets may be provided to a ring-shaped magnetic casing and directions of magnetic poles of adjacent columnar anisotropic segment magnets may be reverse to each other. With this configuration, magnetic force lines may be formed between adjacent segment magnets, and a magnetic field may be formed only at a peripheral portion of a processing space between the upper electrode 105 and the lower electrode 110. Thus, the plasma can be confined in the processing space.

In accordance with the above-described configuration as described above, the upper electrode 105a is an example of the electrode of the RIE plasma processing apparatus. The upper electrode 105a may include a base member 105a made of a dielectric material and having therein a certain space U; a cover 107 for airtightly sealing the certain space U and isolating the space U from the plasma generation space when mounting the electrode to the plasma processing apparatus; and multiple gas hole tubes 105e, passing through the cover member 107, the space U and the base member 105a, each gas hole tube having a gas hole isolated from the certain space U.

(Electrode Structure)

Hereinafter, structure and operation of the upper electrode 105 provided at the RIE plasma etching apparatus of the present embodiment will be described in detail. FIG. 2A is a vertical cross sectional view of a general upper electrode, and FIG. 2B is a vertical cross sectional view of the upper electrode 105 of the present embodiment.

(Control of Electric Field Intensity Distribution)

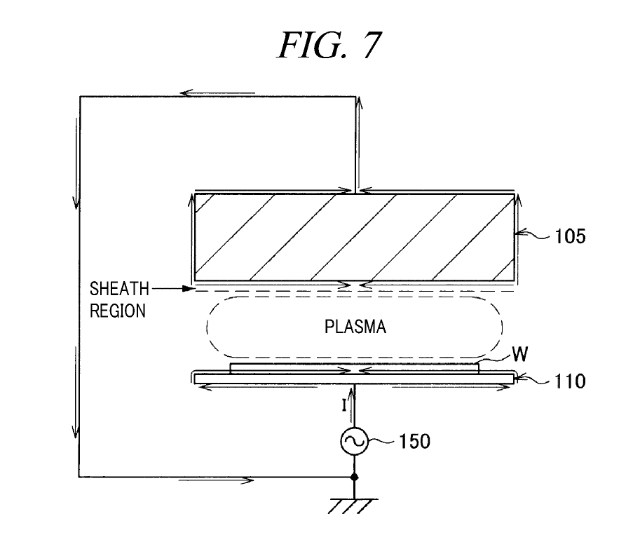

A distribution of capacitance (electrostatic capacitance) illustrated in FIG. 2A may be uniform because the base member 105a made of a dielectric material has a flat shape. Referring to FIG. 2A, plasma density distribution may be increased toward a central portion of a plasma generation space and may be decreased toward an edge portion thereof. This is because, as described above, when a frequency of a power supplied from a high frequency power supply 150 shown in FIG. 7 is increased, a high frequency current may flow along the surface of the lower electrode 110 and then may flow along the top surface of the lower electrode 110 from the edge portion toward the central portion thereof by a skin effect. Accordingly, the electric field intensity at the central portion of the lower electrode 110 may become higher than electric field intensity at the edge portion thereof, and this accelerates ionization of dissociation of a gas. Therefore, the electron density of plasma at the central portion of the lower electrode 110 may become higher than electron density of plasma at the edge portion thereof. As a result, resistivity of plasma at the central portion of the lower electrode 110 may become lower than resistivity of plasma at the edge portion thereof. This may allow a high frequency current to be concentrated at the central portion of the upper electrode 105, so that the plasma density at the central portion of the upper electrode 105 may become higher than the plasma density at the edge portion thereof.

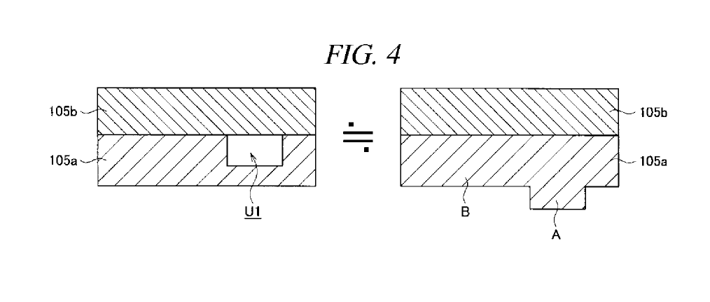

In the upper electrode 105 of the present embodiment shown in FIG. 2B, the recess 105a1 may be formed at the upper central portion of the base member 105a, and the space U may be formed by airtightly sealing the recess 105a1 with the cover 107. With this configuration, the space U inside the recess 105a1 can be considered as a dielectric layer having a space dielectric constant (∈₀) of 1. Accordingly, there is made a difference between a dielectric constant (∈) of the base base member 105a and the dielectric constant (∈₀) of the space U. Here, the dielectric constant (∈₀) of the space U may be about 1, which is the lowest value among the dielectric constants of dielectric materials. In view of the electrostatic capacitance, an area where the space U1 is formed as depicted in a left part of FIG. 4 has an effect equal to a structure where a dielectric member of the base member becomes thick as depicted as a portion A protruding from a flat portion B in a right part of FIG. 4. Therefore, in examples shown in FIGS. 5A to 5C, the capacitance difference between the space portion and the non-space portion can be more increased when the entire space U is formed as the hollow region as shown in FIGS. 5A and 5B as compared to when fine holes 90 are formed in the space as shown in FIG. 5C. In other words, it is equivalent to a case where the portion A shown in FIG. 4 is more protruded from the flat portion B.

Based on this principle, by forming the space U inside the base member 105a of the upper electrode 105 of the present embodiment, the electrostatic capacitance at the central portion of the base member 105a may become smaller than that of the peripheral portion of the base member 105a. Therefore, it is possible to achieve an effect equal to a case where the dielectric member of the base member 105a becomes thicker at the central portion than the periphery portion thereof, that is, an effect of making it difficult for a high frequency to easily escape from the space than other portion. Accordingly, in the present embodiment, the plasma density at the central portion of the base member 105a can be decreased by using the upper electrode 105 mainly including the base member 105a and the cover 107 made of homogeneous materials. Further, the electric field distribution of the high frequency power for plasma generation can be uniformized. As a result, the density distribution of plasma can be uniformized.

Further, in the present embodiment, the depth of the recess 105a1 may be varied within the range in which the recess 105a1 does not penetrate the plasma space. Specifically, the recess 105a1 may be formed such that the depth thereof may be increased toward a central portion and decreased toward a peripheral portion. Accordingly, as shown in FIG. 2B, the distribution of the electrostatic capacitance at the central portion within the base member 105a can be gradually decreased so as to be lower than the distribution of the electrostatic capacitance at the peripheral portion thereof. As a result, the distribution of the plasma density can be further uniformized.

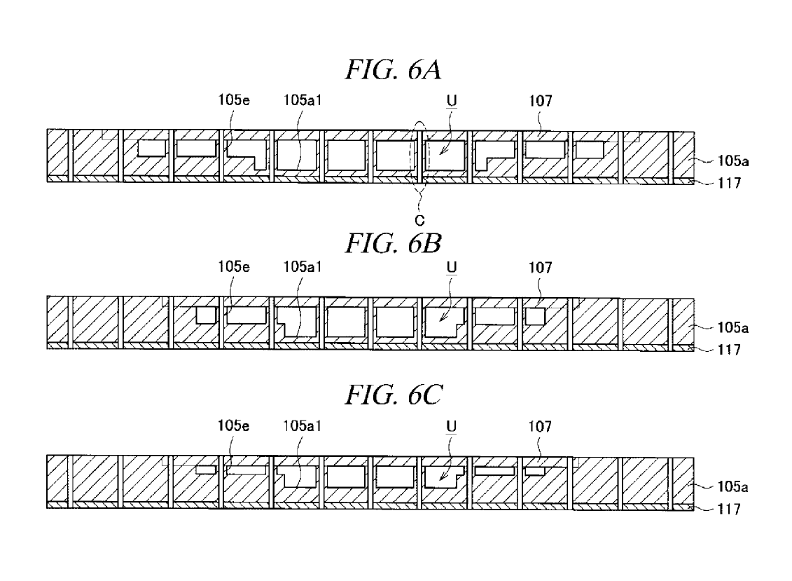

In addition, the depth or the width of the recess 105a1 may not be limited to that of the above-described embodiment. For example, it may be desirable to adjust the recess 105a1 at a position where the plasma density is high to have a large depth the recess 105a1 and to adjust the recess 105a1 at a position where the plasma density is low to have a shallow depth. Specifically, the width of the recess 105a1 can be adjusted, without adjusting the depth of the recess 105a1. By way of example, the recess 105a1 shown in FIG. 6A is adjusted to have a greater width than the recess 105a1 shown in FIG. 6B. Alternatively, the depth of the recess 105a1 can be adjusted, without adjusting the width of the recess 105a1. By way of example, the recess 105a1 shown in FIG. 6B is adjusted to have a greater depth than the recess 105a1 shown in FIG. 6C. Further alternatively, both the width and the depth of the recess 105a1 shown in FIG. 6A can be adjusted to be equal to those of the recess 105a1 shown in FIG. 6C. In accordance with the present embodiment, the upper electrode 105 can be fabricated to meet the requirements of each process and each apparatus simply by mechanically processing the recess 105a1 in a desired depth and width. Accordingly, the distribution of the plasma density can be further uniformized.

(Diffusion Joint)

The base member 105a and the cover 107 may be made of silicon oxide, and connected to each other by diffusion joint. As a consequence, an airtight space U can be formed in the recess 105a1. Specifically, first of all, the base member 105a and the cover 107 may be connected to each other, and then, heated and pressed under a vacuum state or a controlled atmosphere such as an atmosphere filled with an inert gas or the like. The base member 105a and the cover 107 may be connected by using diffusion of atoms in the contact surface under a temperature slightly lower than the melting point of the material (silicon oxide) of the base member 105a and the cover 107 (diffusion joint).

Desirably, the space U may be in the atmospheric state than in the depressurized state. The atmospheric pressure may be within the range of about 760 mTorr±100 mTorr. As a consequence, abnormal electric discharge can be prevented from occurring in the space U. However, it is required that the space U does not communicate with the plasma generation space in the processing chamber. Further, the space U may be in a vacuum state instead of being filled with the atmosphere, or may be sealed with an inert gas in the atmospheric state or the depressurized state.

In order to form the gas holes in a shower head shape, holes are formed in the gas hole tubes 105e that are arranged in the base member 105a at a regular interval in the space U, as depicted by “C” in FIG. 6A, for example. Accordingly, it may be possible to form the gas hole tubes 105e which isolate the gas holes 105c from the space U.

The space U may be formed by firmly providing the cover 107 over the recess 105a1. Further, by providing the gas hole tubes 105e isolated from the space U, the space U inside the recess 105a1 may be isolated from a plasma generation space in the processing chamber or from the gas holes 105c. Accordingly, the gas or the plasma can be prevented from entering into the space U. As a consequence, abnormal electric discharge can be prevented from occurring in the space U, and the capacitance difference between the portion where the space U exists and the portion where the space U does not exist can be more increased. Especially, even when the high frequency power applied to the upper electrode 105 or the lower electrode 110 has a frequency greater than or equal to about 100 MHz, it is possible to prevent abnormal electric discharge in the space U from occurring.

As can be seen from FIG. 6A to 6C, the surface of the base member 105a's surface (here, the bottom surface) facing the plasma generation space may be covered by a plate-shaped electrode cover 117 made of the same material as that of the base member 105a. Accordingly, the damage of the base member 105a by the plasma can be reduced. The electrode cover 117 can be exchanged depending on the degree of damage.

The diameter of each gas hole 105c may be from about 0.3 mm to about 1 mm. The thickness of each the gas hole tube 105e may need to be considered based on the material of the gas hole tubes 105e. Therefore, each gas hole tube 105e may have an inner diameter of about 0.3 mm to about 1 mm, and an outer diameter of about 5 mm to about 10 mm.

Further, since the dielectric constant of the thickness portion (from the inner diameter to the outer diameter) of the gas hole tubes 105e is not equal to the space dielectric constant (∈₀), it may be desirable to reduce the thickness of the gas hole tubes 105e in consideration of strength or fabrication process. For example, when the gas hole tubes 105e are made of silicon oxide (SiO₂), the base member 105a and the cover 107 can be connected to each other by diffusion joint. Therefore, the thickness of each gas hole tube 105e may not need to be increased, which is advantageous. Meanwhile, when the gas hole tubes 105e are made of alumina (Al₂O₃), silicon nitride (Si₃N₄), or aluminum nitride (AlN), adhesive may need to be used for bonding the base member 105a and the cover 107. For that reason, a certain level of the thickness of each gas hole tube 105e may be required, which is disadvantageous as compared to the case of diffusion joint. Meanwhile, when the cover 107 is bonded to the base member 105a, since there are some limitations in the bonding processing, it may be desirable to reduce the diameter of the cover 107 in order to reduce the contact surface between the cover 107 and the base member 105a.

As described above, in accordance with the electrode of the present embodiment, it is possible to uniformize the plasma density by controlling the distribution of the electric field intensity of the high frequency power for plasma generation while preventing occurrence of abnormal electric discharge in the upper electrode 105 through the space U in the upper electrode 105.

The embodiment of the present disclosure has been described with reference to the accompanying drawings, but the present disclosure is not limited to this embodiment. It would be understood by those skilled in the art that all modification and embodiments conceived from the meaning and scope of the claims and their equivalents are included in the scope of the present disclosure.

For example, in the above-described embodiment, the recess 105a1 may be formed such that the upper portion of the base member 105a becomes open. With this configuration, the contact surface of the cover 107 may be located apart from the plasma generation space, so that the contact surface does not face the plasma generation space. However, the recess 105a1 may be formed at the lower portion of the base member 105a, and the cover 107 may be connected to the lower portion of the base member 105a.

In the present embodiment, the space U is formed in the upper electrode 105 serving as the first electrode, and the space U is not be formed in the lower electrode 110 serving as the second electrode. However, the space U may be formed in the lower electrode 110, but may not be formed in the upper electrode 105. Alternatively, the space U may be formed in both of the upper electrode and the lower electrode.

Further, in the above-described embodiment, the high frequency power for plasma excitation has been applied to the lower electrode. However, the present disclosure is not limited thereto. For example, the high frequency power for plasma excitation may be applied to any one of the upper electrode and the lower electrode, or to both of the upper electrode and the lower electrode.

The plasma processing apparatus of the present disclosure is not limited to a parallel plate type plasma processing apparatus. The plasma processing apparatus of the present disclosure can also be used for any one of other plasma processing apparatuses such as an inductively coupled plasma processing apparatus, a microwave plasma processing apparatus or the like, in addition to a capacitively coupled (parallel plate type) plasma processing apparatus.

Further, in the above-described embodiment, the plasma processing apparatus is limited to the plasma etching apparatus. However, the present disclosure is not limited thereto. For example, the present disclosure can be applied to a plasma processing apparatus for performing a plasma process on an object to be processed by exciting a plasma, such as a film forming apparatus, an etching apparatus or the like.

The object to be processed may be a silicon wafer or a glass substrate.

What is claimed is:

1. An electrode for a plasma processing apparatus capable of supplying a gas, the electrode comprising:
a base member made of a dielectric material and having therein a space;
a cover member for airtightly sealing the space and isolating the space from a plasma generation space when the electrode is installed at the plasma processing apparatus; and
a plurality of gas hole tubes passing through the cover member, the space and the base member, each gas hole tube having a gas hole isolated from the space.

2. The electrode of claim 1,
wherein the space has an atmospheric pressure.

3. The electrode of claim 1,
wherein the space is formed by a recess formed in the base member,
the cover member is configured to seal the recess, and
the recess is airtightly sealed by performing diffusion joint between the cover member and the base member made of silicon oxide.

4. The electrode of claim 3,
wherein the recess has a taper shape or a step shape.

5. The electrode of claim 4,
wherein the recess is formed such that a depth thereof becomes deeper toward a central portion and becomes shallower toward a peripheral portion thereof.

6. The electrode of claim 1,
wherein the plurality of gas hole tubes are spaced apart from each other at a regular interval to supply a gas in a shower shape.

7. The electrode of claim 1, further comprising:
a plate-shaped electrode cover made of a material same as that of the base member, and provided adjacent to a surface of the electrode facing the plasma generation space.

8. The electrode of claim 1,
wherein each gas hole tube has a diameter of about 5 mm to about 10 mm.

9. A plasma processing apparatus comprising:
a processing chamber;
a first electrode and a second electrode facing each other in the processing chamber, and having a plasma generation space therebetween; and
a gas supply source for supplying a gas into the processing chamber,
wherein the first electrode includes a base member made of a dielectric material and having therein a space;
a cover member for airtightly sealing the space and isolating the space from a plasma generation space when the electrode is installed at the plasma processing apparatus; and
a plurality of gas hole tubes passing through the cover member, the space and the base member, each gas hole tube having a gas hole isolated from the space.

10. The plasma processing apparatus of claim 9,
wherein the space has an atmospheric pressure.

11. The plasma processing apparatus of claim 9,
wherein the first electrode is an upper electrode.
